(19) United States
(12) Patent Application Publication
(10) Pub. No.: US 2024/0429309 A1
(43) Pub. Date: Dec. 26, 2024

(54) QUANTUM DEVICE AND QUANTUM DEVICE MANUFACTURING METHOD

(71) Applicant: NEC Corporation, Minato-ku, Tokyo (JP)

(72) Inventors: Kunihiko ISHIHARA, Toyko (JP); Yuichi Igarashi, Tokyo (JP); Katsumi Kikuchi, Tokyo (JP)

(73) Assignee: NEC Corporation, Minato-ku, Tokyo (JP)

(21) Appl. No.: 18/731,568

(22) Filed: Jun. 3, 2024

(30) Foreign Application Priority Data
Jun. 21, 2023 (JP) 2023-101575

(51) Int. Cl. H01L 29/66; G06N 10/40; H01L 23/50

(52) U.S. Cl. CPC H01L 29/66977; G06N 10/40; H01L 23/50

(57) ABSTRACT

A quantum device includes a first chip including a quantum bit including a band-shaped pattern extending in a first direction, and a second chip including a band-shaped readout pad extending in a second direction different from the first direction, wherein the readout pad faces and intersects with the band-shaped pattern.

### CROSS-REFERENCE TO RELATED APPLICATION

Priority is claimed on Japanese Patent Application No. 2023-101575, filed Jun. 21, 2023, the content of which is incorporated herein by reference.

### TECHNICAL FIELD

The present disclosure relates to a quantum device and a quantum device manufacturing method.

### BACKGROUND ART

A device including quantum bits and readout pads is known as a quantum device. For example, Japanese Patent No. 6810280 (hereinafter Patent Document 1) discloses a quantum device including a first chip that includes an array of superconducting qubits that are Xmons and a second chip that includes an array of pad elements capacitively coupled to the superconducting qubits.

### SUMMARY

Each pad element disclosed in Patent Document 1 is aligned on the center of the corresponding Xmon.

Therefore, if the position of the pad element deviates from the center of the Xmon, for example, the magnitude of capacitive coupling between the Xmon and the pad element may change.

An example object of the present disclosure is to provide a quantum device and a quantum device manufacturing method for solving the above-mentioned problem.

### Solution to Problem

A quantum device according to one example aspect of the present disclosure includes a first chip including a quantum bit including a band-shaped pattern extending in a first direction, and a second chip including a band-shaped readout pad extending in a second direction different from the first direction, wherein the readout pad faces and intersects with the band-shaped pattern.

A quantum device manufacturing method according to one example aspect of the present disclosure includes preparing a first chip including a quantum bit including a band-shaped pattern and a second chip including a band-shaped readout pad, and bonding the first chip and the second chip such that a first direction in which the band-shaped pattern extends and a second direction in which the readout pad extends are different, and the band-shaped pattern and the readout pad face each other and intersect with each other.

According to the above aspect, changes in capacitive coupling can be curbed.

### BRIEF DESCRIPTION OF THE DRAWINGS

FIG. 1 is a cross-sectional view of a quantum device according to some example embodiments of the present disclosure.

FIG. 2 is an enlarged view of part II in FIG. 1.

FIG. 3 is a cross-sectional view taken along line III-III in FIG. 2.

FIG. 4 is a diagram illustrating the operation of a quantum device according to some example embodiments of the present disclosure.

FIG. 5 is a flowchart of a quantum device manufacturing method according to some example embodiments of the present disclosure.

FIG. 6 is a diagram illustrating a relationship between a quantum bit and a readout pad according to a comparative example.

FIG. 7 is an explanatory diagram of the operation and effects of the quantum device according to some example embodiments of the present disclosure.

FIG. 8 is a diagram illustrating a relationship between a quantum bit and a readout pad according to a comparative example.

FIG. 9 is a cross-sectional view of a quantum device according to some example embodiments of the present disclosure.

FIG. 10 is a cross-sectional view of a quantum device according to some example embodiments of the present disclosure.

FIG. 11 is a cross-sectional view of a quantum device according to some example embodiments of the present disclosure.

FIG. 12 is a cross-sectional view of a quantum device according to some example embodiments of the present disclosure.

FIG. 13 is a cross-sectional view of a quantum device according to some example embodiments of the present disclosure.

FIG. 14 is a cross-sectional view taken along the line XIV-XIV in FIG. 13.

### EXAMPLE EMBODIMENT

Hereinafter, various example embodiments according to the present disclosure will be described using the drawings.

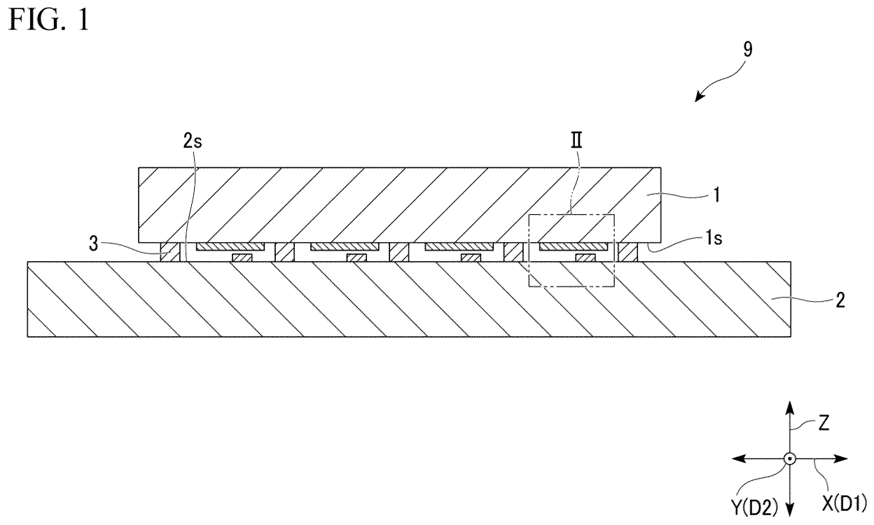

Hereinafter, some example embodiments of the present disclosure will be described using FIG. 1 to FIG. 8.

### (Configuration of Quantum Device)

A quantum device 9 is a device implemented in a quantum computer.

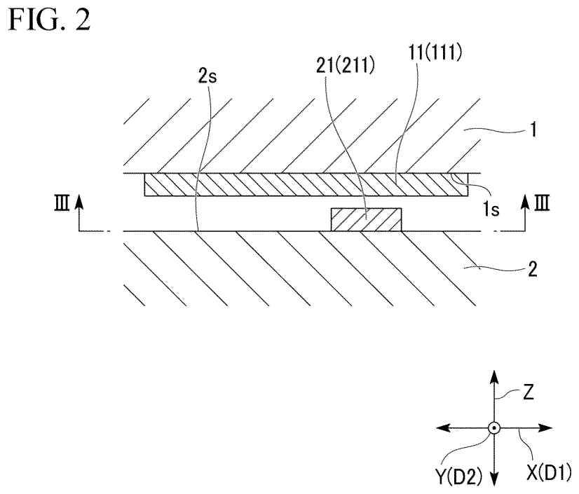

As shown in FIGS. 1 and 2, the quantum device 9 includes a first chip 1, a second chip 2, and bumps 3.

The first chip 1 has a plate shape.

The first chip 1 has a first plane Is as a plate surface on the side facing the second chip 2.

The second chip 2 has a plate shape.

The second chip 2 has a second plane 2s, which is wider than the first plane 1s, as a plate surface on the side facing the first chip 1.

The first chip 1 and the second chip 2 are laminated with the bumps 3 interposed therebetween such that the first plane 1s and the second plane 2s face each other and are separated from each other.

### (Detailed Configuration of First Chip)

The first chip 1 is a quantum chip.

The first chip 1 includes a plurality of quantum bits 11.

The plurality of quantum bits 11 are provided on the first plane 1s.

The plurality of quantum bits 11 are arranged in an array in a plane along the first plane 1s.

Hereinafter, the lamination direction of the first chip 1 and the second chip 2 is referred to as a Z direction, a first direction D1 within the first plane 1s is referred to as an X direction, and a second direction D2 different from the first direction D1 within the first plane 1s is referred to as a Y direction.

For example, the Z direction may be a vertical direction, and the X-direction and Y-direction may be a horizontal direction.

For example, the Z direction, the X direction, and the Y direction may be directions perpendicular to each other.

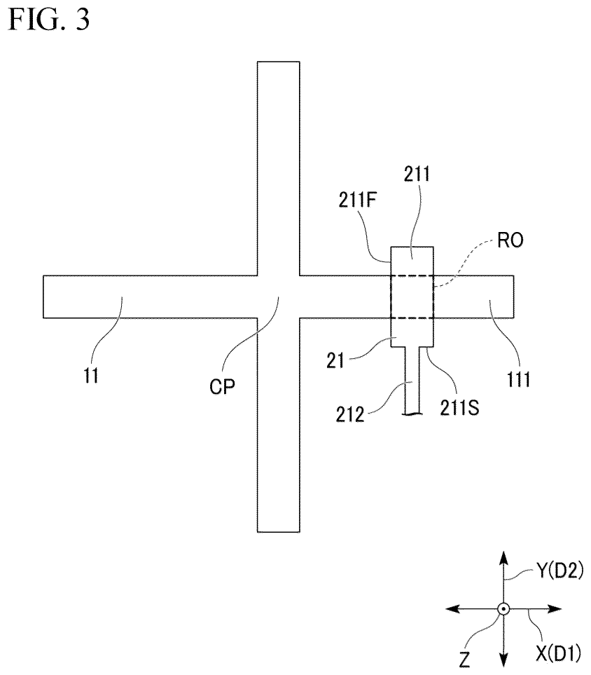

As shown in FIGS. 2 and 3, each quantum bit 11 includes a band-shaped pattern 111 extending in the first direction D1.

For example, each quantum bit 11 may be an Xmon, and the entire quantum bit 11 may have a cross-shaped thin film pattern when viewed in the Z direction. At this time, each quantum bit 11 may include the band-shaped pattern 111 as part of the cross-shaped thin film pattern.

Here, the cross shape of each quantum bit 11 has a pair of arms extending in opposite directions in the X direction, and a pair of arms extending in opposite directions in the Y direction.

Specifically, the band-shaped pattern 111 may be a pattern of one arm part having a band shape protruding from the intersection point CP of the cross shape to one side in the X direction among the patterns of four arm parts of the cross shape.

Here, the cross-shaped thin film pattern of each quantum bit 11 functions as a resonant circuit for microwaves confined in the quantum bit 11.

For example, the cross-shaped thin film pattern of each quantum bit 11 may be entirely made of a superconductor.

In the present disclosure, the superconductor may be a substance that functions as a superconductor at extremely low temperatures.

For example, the superconductor may be Nb, which functions as a superconductor at 9.2 K or lower.

For example, the superconductor may be Al, which functions as a superconductor at 1.2 K or less.

### (Detailed Configuration of Second Chip)

The second chip 2 is a readout chip.

For example, the second chip 2 is an interposer that reads out information stored in the first chip 1 and outputs the information to the outside of the quantum device 9.

The second chip 2 includes a plurality of readout circuits 21.

The plurality of readout circuits 21 are arranged in an array in a plane along the second plane 2s.

Each readout circuit 21 includes a readout pad 211 and a lead line 212.

The readout pad 211 faces the corresponding quantum bit 11 among the plurality of quantum bits 11 on a one-to-one basis.

The readout pad 211 is provided on the second plane 2s.

The readout pad 211 has a band shape extending in the second direction D2 (Y direction).

The length of the readout pad 211 in the Y direction is greater than the width of the band-shaped pattern 111 in the Y direction.

The readout pad 211 has a parallel first pair of sides 211F that intersects with the band-shaped pattern 111, and a parallel second pair of sides 211S that does not intersect with the band-shaped pattern 111.

For example, the readout pad 211 may have a rectangular shape having long sides at both ends in the X direction as the first pair of sides 211F and short sides at both ends in the Y direction as the second pair of sides 211S.

The band-shaped readout pad 211 intersects with the opposite band-shaped pattern 111. Therefore, when viewed in the Z direction, the band-shaped pattern 111 and the readout pad 211 have an overlapping portion RO where they overlap each other in the middle portion of each pattern.

That is, the shape of the readout pad 211 extends to both sides in the Y direction, which is the width direction of the band-shaped pattern 111, while maintaining the width of the intersecting overlapping portion RO, with a width that is same as a width of the overlapping portion RO.

For example, the length by which the readout pad 211 protrudes from the overlapping portion RO in the Y direction may be greater than a positional deviation tolerance in the Y direction when the first chip 1 and the second chip 2 are bonded.

On the other hand, the shape of the band-shaped pattern 111 extends to both sides in the X direction, which is the width direction of the readout pad 211, while maintaining the width of the intersecting overlapping portion RO, with a width that is same as a width of the overlapping portion RO.

For example, the length by which the band-shaped pattern 111 protrudes from the overlapping portion RO in the X direction may be greater than a positional deviation tolerance in the X direction when the first chip 1 and the second chip 2 are bonded.

For example, the shape of the band-shaped pattern 111 in the overlapping portion RO and the portion protruding from the overlapping portion RO in the X direction may be a shape that hardly changes within the range of the positional deviation tolerance in the X direction when the first chip 1 and the second chip 2 are bonded.

The positional deviation tolerance in the X direction and the positional deviation tolerance in the Y direction may be, for example, 0±5 μm.

The lead line 212 is provided on the second plane 2s.

The lead line 212 extends from one of the second pair of sides 211S of the readout pad 211 in the second direction D2.

Specifically, the lead line 212 protrudes from the center of the second pair of sides 211S and extends linearly in the Y direction with a width in the X direction that is less than the width of the readout pad 211 in the X direction.

### (Operation of Quantum Device)

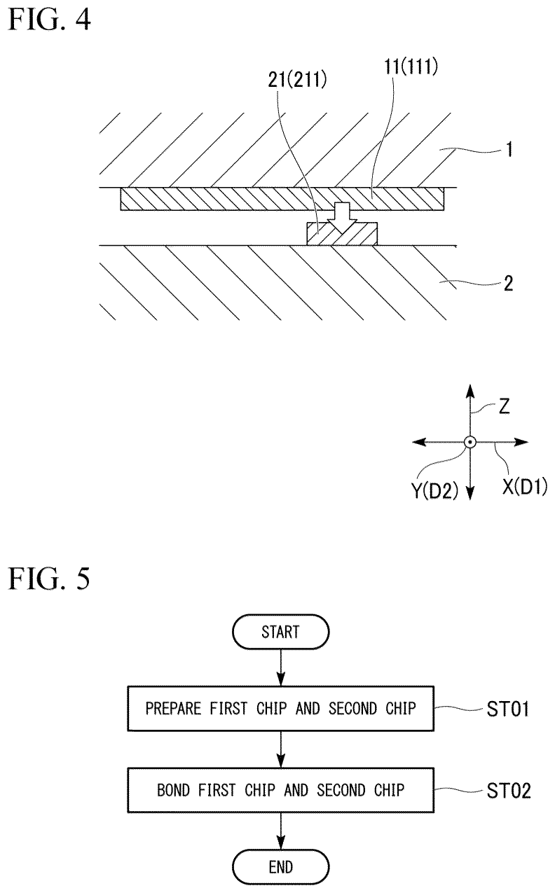

The readout circuit 21 reads out information stored in the corresponding quantum bit 11. At this time, the readout pad 211 is capacitively coupled to the band-shaped pattern 111 through a gap formed between the first plane 1s and the second plane 2s, and thus the readout circuit 21 reads out the information stored in the quantum bit 11, as shown in FIG. 4.

### (Quantum Device Manufacturing Method)

As shown in FIG. 5, an operator prepares the first chip 1 including the quantum bit 11 including the band-shaped pattern 111 and the second chip 2 including the band-shaped readout pad 211 (ST01). At this time, the operator may place a material for forming the bumps 3 between the first chip 1 and the second chip 2.

Subsequently to ST01, the operator bonds the first chip 1 and the second chip 2 such that the first direction D1 in which the band-shaped pattern 111 extends and the second direction D2 in which the readout pad 211 extends are different, and the band-shaped pattern 111 and the readout pad 211 face and intersect with each other (ST02). At this time, the operator may heat the material for forming the bumps 3 and bond the first chip 1 and the second chip 2 with the bumps 3.

In ST02, for example, the operator may bond the first chip 1 and the second chip 2 such that the shape of the readout pad 211 extends to both sides of the band-shaped pattern 111 in the width direction which is the second direction D2 while maintaining the width of the intersecting overlapping portion.

In ST02, for example, the operator may bond the first chip 1 and the second chip 2 such that the shape of the band-shaped pattern 111 extends to both sides of the readout pad 211 in the width direction while maintaining the width of the intersecting overlapping portion RO.

In ST02, for example, the operator may bond the first chip 1 and the second chip 2 such that the length of the readout pad 211 in the second direction D2 is greater than the width of the band-shaped pattern 111 in the second direction D2.

In ST02, for example, the operator may bond the first chip 1 and the second chip 2 such that the band-shaped pattern 111 and the readout pad 211 are capacitively coupled.

In ST02, for example, the operator may bond the first chip 1 and the second chip 2 such that the lead line 212 extends in the second direction D2.

### (Operation and Effects)

In the quantum device 9 of the present example embodiments, the band-shaped readout pad 211 extending in the second direction D2 faces and intersects with the band-shaped pattern 111 extending in the first direction D1.

Accordingly, even if the readout pad 211 deviates in the first direction D1 or the second direction D2 with respect to the band-shaped pattern 111, it is difficult for the area of the overlapping portion RO to change.

For example, even if a positional deviation of the second chip 2 with respect to the first chip 1 occurs in the bonding process of the quantum device 9, it is difficult for the magnitude of capacitive coupling between the quantum bit 11 and the readout pad 211 to change.

Therefore, the quantum device 9 of the present example embodiments can curb changes in capacitive coupling.

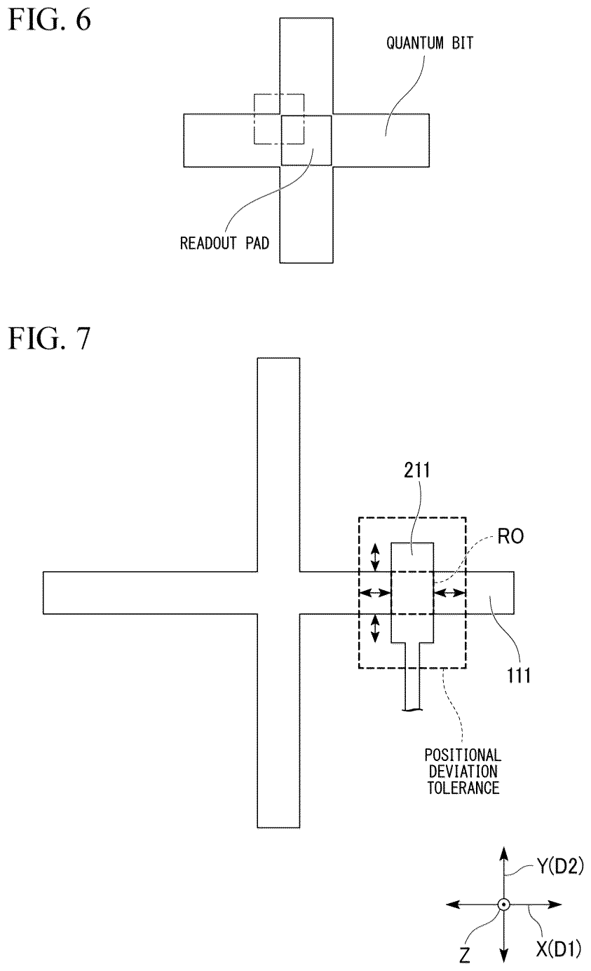

For example, as a comparative example, in a case where a square-shaped readout pad as shown in FIG. 6 overlaps with a cross-shaped intersection of a quantum bit, the area of the overlapping portion easily changes due to deviation of the readout pad.

On the other hand, in the quantum device 9 of the present example embodiments, it is difficult for the area of the overlapping portion RO to change as described above, and thus changes in capacitive coupling can be curbed.

According to the present example embodiments, even if a positional deviation occurs when the first chip 1 and the second chip 2 are bonded, it is difficult for the area of the overlapping portion RO to change if the positional deviation is within a positional deviation tolerance compensated on the basis of the shape of the band-shaped pattern 111 and the shape of the band-shaped readout pad 211.

For example, according to the present example embodiments, when the readout pad 211 is disposed to intersect with the band-shaped pattern 111, as shown in FIG. 7, the length of the readout pad 211 that protrudes in the Y direction from the intersecting overlapping portion RO is greater than the bonding positional deviation tolerance between the first chip 1 and the second chip 2.

On the other hand, in the width direction (X direction) of the readout pad 211, the shape of the quantum bit hardly changes in a range where the length of the bonding positional deviation tolerance between the first chip 1 and the second chip 2 is added to both sides of the readout pad 211.

Accordingly, even if a positional deviation occurs when the first chip 1 and the second chip 2 are bonded, it is difficult for the area of the overlapping portion RO to change if the positional deviation is within the positional deviation tolerance.

Therefore, according to the quantum device 9, it is difficult for the magnitude of capacitive coupling to change, and stable readout performance is guaranteed.

According to the present example embodiments, the shape of the readout pad 211 can be designed independently of the shape of the quantum bit 11. For example, by simply changing the width of the readout pad 211, capacitive coupling can be set to an arbitrary magnitude.

According to the present example embodiments, the lead line 212 extends from one of the second pair of sides 211S of the readout pad 211 that protrudes from both sides of the band-shaped pattern 111 in the Y direction.

Accordingly, it is difficult for the lead line 212 to enter the overlapping portion RO.

Therefore, the quantum device 9 can curb the influence of the lead line 212 on the magnitude of capacitive coupling between the quantum bit 11 and the readout pad 211.

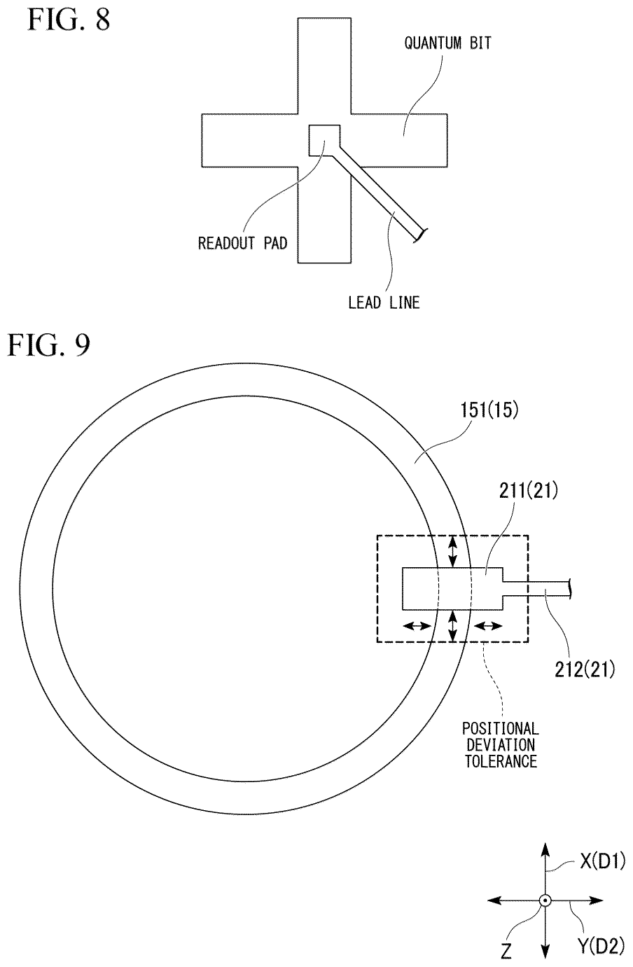

For example, as a comparative example, in the case of a readout pad that is small enough that an overlapping portion intersecting with the quantum bit is included within the quantum bit, as shown in FIG. 8, the quantum bit and the lead line have the overlapping portion. Accordingly, due to deviation of the readout pad, the lead line easily affects the magnitude of capacitive coupling between the quantum bit and the readout pad.

On the other hand, in the quantum device 9 of the present example embodiments, it is difficult for the lead line 212 to enter into the overlapping portion RO, as described above, and thus the influence of the lead line 212 on the magnitude of capacitive coupling between the quantum bit 11 and the readout pad 211 can be curbed.

According to the present example embodiments, the readout pad 211 has the parallel first pair of sides 211F that intersect with the band-shaped pattern 111 and the second pair of sides 211S that do not intersect with the band-shaped pattern 111.

Accordingly, it is difficult for the area of the overlapping portion RO to change due to a positional deviation in the Y direction.

According to the present example embodiments, the readout pad 211 has a shape extending on both sides in the width direction of the band-shaped pattern 111 to maintain the width of the intersecting overlapping portion.

Accordingly, it is difficult for the area of the overlapping portion RO to change due to a positional deviation in the Y direction.

According to the present example embodiments, the length of the readout pad 211 in the second direction D2 is greater than the width of the band-shaped pattern 111.

Accordingly, it is difficult for the area of the overlapping portion RO to change due to a positional deviation in the Y direction.

According to the present example embodiments, the band-shaped pattern 111 and the readout pad 211 are capacitively coupled.

Accordingly, the quantum device 9 can read out information stored in the quantum bit 11 to the outside via the readout pad 211.

### Modified Examples

In one example of the present example embodiments, although the cross-shaped thin film pattern of each quantum bit 11 is entirely made of a superconductor, other components that electromagnetically couple with the quantum bit 11 may also be made of a superconductor.

As a modified example, the readout pad 211 may be composed of a superconductor thin film pattern.

As another modified example, the readout pad 211 and the lead line 212 may be composed of a superconductor thin film pattern.

In one example of the present example embodiments, although the lead line 212 extends in the second direction D2 from the second pair of sides 211S of the readout pad 211, any configuration may be used as long as the influence of the lead line 212 on the magnitude of capacitive coupling between the quantum bit 11 and the readout pad 211 can be curbed.

As a modified example, the lead line 212 may extend from the second pair of sides 211S of the readout pad 211 in a direction other than the second direction D2.

Specifically, the lead line 212 may extend from the second pair of sides 211S of the readout pad 211 in a direction diagonal to the second direction D2.

Hereinafter, some example embodiments of the present disclosure will be described using FIG. 9.

A quantum device of the present example embodiments has the same configuration as the quantum device of the some example embodiments described above, operates in the same manner, is manufactured in the same manner, and has the same effects.

### (Configuration)

The quantum device 9 of the present example embodiments includes each quantum bit 15 as shown in FIG. 9 instead of each quantum bit 11 as shown in FIG. 3.

As shown in FIG. 9, each quantum bit 15 includes a band-shaped pattern 151 extending in the first direction D1.

For example, each quantum bit 15 may have an annular thin film pattern as a whole when viewed in the Z direction. At this time, each quantum bit 15 may include the band-shaped pattern 151 as a portion of the annular thin film pattern.

Specifically, the band-shaped pattern 151 may be a pattern of a portion of the annular pattern that extends in the X direction on the circumference of the annular pattern on one side in the Y direction.

Here, the annular thin film pattern of each quantum bit 15 functions as a resonant circuit for microwaves confined in the quantum bit 15.

For example, the annular thin film pattern of each quantum bit 15 may be entirely made of a superconductor.

On the other hand, with respect to the band-shaped pattern 151, the readout pad 211 has the same shape as the shape with respect to the band-shaped pattern 111 of the some example embodiments described above.

Further, the readout pad 211 is provided in the same positional relationship with respect to the band-shaped pattern 151 as the positional relationship with respect to the band-shaped pattern 111 in the some example embodiments described above.

### (Operation and Effects)

In the quantum device 9 of the present example embodiments, the band-shaped readout pad 211 extending in the second direction D2 faces and intersects with the band-shaped pattern 151 extending in the first direction D1.

Accordingly, even if the readout pad 211 deviates in the first direction D1 or the second direction D2 with respect to the band-shaped pattern 151, it is difficult for the area of the overlapping portion to change.

Therefore, the quantum device 9 of the present example embodiments can also curb changes in capacitive coupling.

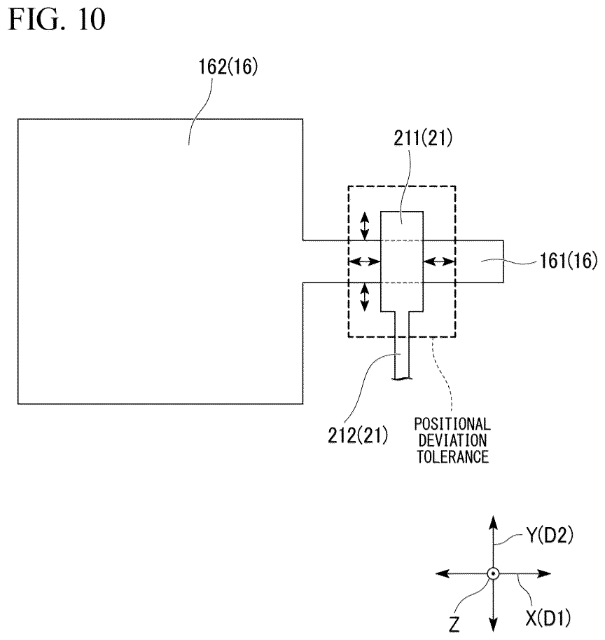

Hereinafter, some example embodiments of the present disclosure will be described using FIG. 10.

A quantum device of the present example embodiments has the same configuration as the quantum device of the some example embodiments described above, operates in the same manner, is manufactured in the same manner, and has the same effects.

### (Configuration)

The quantum device 9 of the present example embodiments includes each quantum bit 16 as shown in FIG. 10 instead of each quantum bit 11 as shown in FIG. 3.

As shown in FIG. 10, each quantum bit 16 includes a band-shaped pattern 161 extending in the first direction D1 and a rectangular pattern 162.

The rectangular pattern 162 is a thin film pattern that has a square shape when viewed in the Z direction and has a pair of sides extending in the first direction D1 and a pair of sides extending in the second direction D2.

The band-shaped pattern 161 is a thin film pattern that extends from the center of one of the pair of sides of the rectangular pattern 162 extending in the second direction D2 to protrude in the first direction D1.

Here, the rectangular pattern 162 and the band-shaped pattern 161 of each quantum bit 16 function as a resonant circuit as a whole for microwaves confined in each quantum bit 16. On the other hand, the band-shaped pattern 161 also functions as a readout bar for providing information to the readout pad 211.

For example, all of the thin film pattern of the rectangular pattern 162 of each quantum bit 16 and the thin film pattern of the band-shaped pattern 161 may be made of a superconductor.

On the other hand, with respect to the band-shaped pattern 161, the readout pad 211 has the same shape as the shape with respect to the band-shaped pattern 111 in the some example embodiments described above.

Further, the readout pad 211 is provided in the same positional relationship with respect to the band-shaped pattern 161 as the positional relationship with respect to the band-shaped pattern 111 in the some example embodiments described above.

### (Operation and Effects)

In the quantum device 9 of the present example embodiments, the band-shaped readout pad 211 extending in the second direction D2 faces and intersects with the band-shaped pattern 161 extending in the first direction D1.

Accordingly, even if the readout pad 211 deviates in the first direction D1 or the second direction D2 with respect to the band-shaped pattern 161, it is difficult for the area of the overlapping portion to change.

Therefore, the quantum device 9 of the present example embodiments can also curb changes in capacitive coupling.

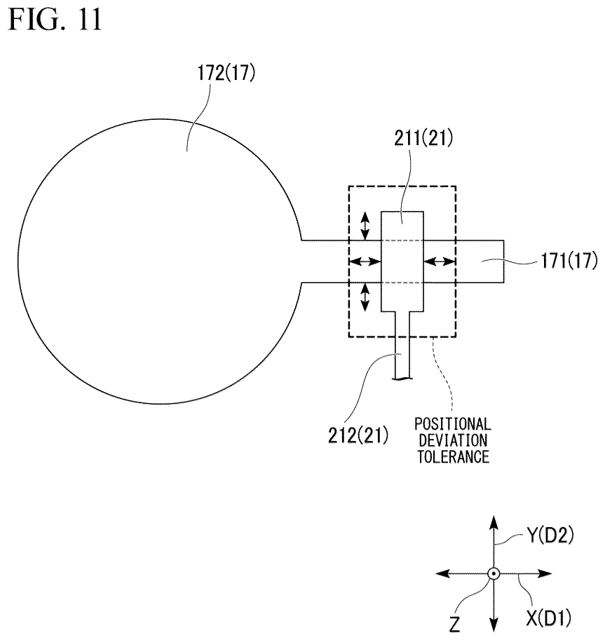

Hereinafter, some example embodiments of the present disclosure will be described using FIG. 11.

A quantum device of the present example embodiments has the same configuration as the quantum device of the some example embodiments described above, operates in the same manner, is manufactured in the same manner, and has the same effects except for the points shown below.

### (Configuration)

The quantum device 9 of the present example embodiments includes each quantum bit 17 as shown in FIG. 11 instead of each quantum bit 11 as shown in FIG. 3.

As shown in FIG. 11, each quantum bit 17 includes a band-shaped pattern 171 extending in the first direction D1 and a circular pattern 172.

The circular pattern 172 is a thin film pattern that has a circular shape as a whole when viewed in the Z direction.

The band-shaped pattern 171 is a thin film pattern that extends to protrude in the first direction D1 from the center of one side portion of the circumference of the circular pattern 172 extending in the second direction D2.

Here, the circular pattern 172 and the band-shaped pattern 171 of each quantum bit 17 function as a resonant circuit as a whole for microwaves confined in each quantum bit 17. On the other hand, the band-shaped pattern 171 also functions as a readout bar for providing information to the readout pad 211.

For example, all of the thin film pattern of the circular pattern 172 and the thin film pattern of the band-shaped pattern 171 of each quantum bit 17 may be made of a superconductor.

On the other hand, with respect to the band-shaped pattern 171, the readout pad 211 has the same shape as the shape with respect to the band-shaped pattern 111 of the some example embodiments described above.

Further, the readout pad 211 is provided in the same positional relationship with respect to the band-shaped pattern 171 as the positional relationship with the band-shaped pattern 111 in the some example embodiments described above.

### (Operation and Effects)

In the quantum device 9 of the present example embodiments, the band-shaped readout pad 211 extending in the second direction D2 faces and intersects with the band-shaped pattern 171 extending in the first direction D1.

Accordingly, even if the readout pad 211 deviates in the first direction D1 or the second direction D2 with respect to the band-shaped pattern 171, it is difficult for the area of the overlapping portion to change.

Therefore, the quantum device 9 of the present example embodiments can also curb changes in capacitive coupling.

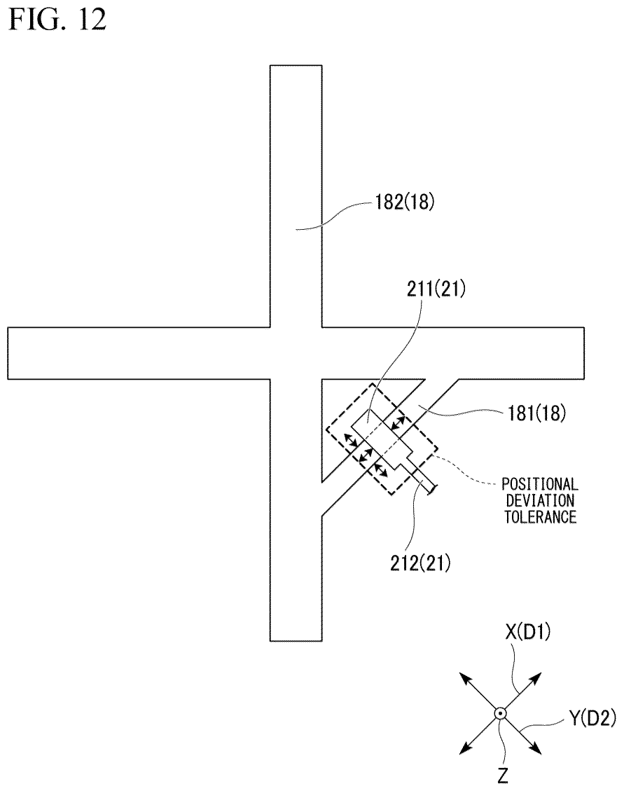

Hereinafter, some example embodiments of the present disclosure will be described using FIG. 12.

A quantum device of the present example embodiments has the same configuration as the quantum device of the some example embodiments described above, operates in the same manner, is manufactured in the same manner, and has the same effects except for the points shown below.

### (Configuration)

The quantum device 9 of the present example embodiments includes each quantum bit 18 as shown in FIG. 12 instead of each quantum bit 11 as shown in FIG. 3.

As shown in FIG. 12, each quantum bit 18 includes a band-shaped pattern 181 extending in the first direction D1 and a cross-shaped pattern 182.

The cross-shaped pattern 182 is a cross-shaped thin film pattern when viewed in the Z direction.

Here, the cross shape of the cross-shaped pattern 182 has a pair of arms extending in 45° counterclockwise direction with respect to the X direction and in opposite directions, and a pair of arms extending in 45° counterclockwise with respect to the Y direction and in opposite directions.

The band-shaped pattern 181 is a thin film pattern that extends in a band shape in the first direction D1 and connects the central portions of the patterns of two adjacent arm parts across a line extending in one direction in the Y direction, among the patterns of four arm parts in the cross shape of the cross-shaped pattern 182.

Here, the cross-shaped pattern 182 and the band-shaped pattern 181 of each quantum bit 18 function as a resonant circuit as a whole for microwaves confined in each quantum bit 18. On the other hand, the band-shaped pattern 181 also functions as a readout bar for providing information to the readout pad 211.

For example, all of the thin film pattern of the cross-shaped pattern 182 and the thin film pattern of the band-shaped pattern 181 of each quantum bit 18 may be made of a superconductor.

On the other hand, with respect to the band-shaped pattern 181, the readout pad 211 has the same shape as the shape with respect to the band-shaped pattern 111 of the some example embodiments.

Further, the readout pad 211 is provided in the same positional relationship with respect to the band-shaped pattern 181 as the positional relationship with respect to the band-shaped pattern 111 of the some example embodiments.

### (Operation and Effects)

In the quantum device 9 of the present example embodiments, the band-shaped readout pad 211 extending in the second direction D2 faces and intersect with the band-shaped pattern 181 extending in the first direction D1.

Accordingly, even if the readout pad 211 deviates in the first direction D1 or the second direction D2 with respect to the band-shaped pattern 181, it is difficult for the area of the overlapping portion to change.

Therefore, the quantum device 9 of the present example embodiments can also curb changes in capacitive coupling.

Furthermore, according to the quantum device 9 of the present example embodiments, the space between the two arms can be effectively used as the band-shaped pattern 181, resulting in high space efficiency.

Therefore, according to the quantum device 9 of the present example embodiments, miniaturization can be achieved.

Although the band-shaped pattern 181 connects the center portions of the patterns of two adjacent arm parts in the present example embodiments, the connected portions are not limited to the center portions and the patterns of the two adjacent arm parts may be connected in any way as long as they extend in the first direction D1.

As a modified example, the band-shaped pattern 181 may connect portions of two adjacent arm parts closer to the tips of the arm parts rather than the center portions of the patterns.

As another modified example, the band-shaped pattern 181 may connect portions of two adjacent arm parts closer to the cross-shaped intersection rather than the center portions of the patterns.

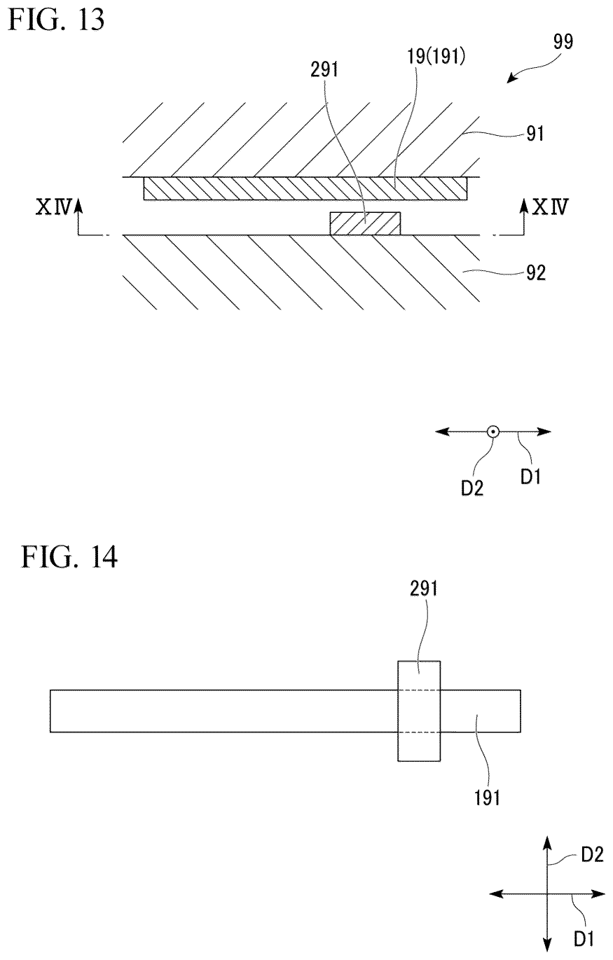

Hereinafter, some example embodiments of the present disclosure will be described below using FIGS. 13 and 14.

### (Configuration)

As shown in FIG. 13, a quantum device 99 of the present example embodiments includes a first chip 91 and a second chip 92.

As shown in FIGS. 13 and 14, the first chip 91 includes a quantum bit 19 including a band-shaped pattern 191 extending in the first direction D1.

The second chip 92 includes a band-shaped readout pad 291 extending in the second direction D2 different from the first direction D1.

The readout pad 291 faces and intersects with the band-shaped pattern 191.

### (Operation and Effects)

In the quantum device 99 of the present example embodiments, the band-shaped readout pad 291 extending in the second direction D2 faces and intersects with the band-shaped pattern 191 extending in the first direction D1.

Accordingly, even if the readout pad 291 deviates in the first direction D1 or the second direction D2 with respect to the band-shaped pattern 191, it is difficult for the area of the overlapping portion to change.

Therefore, the quantum device 99 of the present example embodiments can curb changes in capacitive coupling.

Hereinafter, some example embodiments of the present disclosure will be described using FIG. 5.

### (Configuration)

As shown in FIG. 5, in a quantum device manufacturing method, a first chip including a quantum bit including a band-shaped pattern and a second chip including a band-shaped readout pad are prepared (ST01).

The first chip and the second chip are bonded such that the first direction in which the band-shaped pattern extends and the second direction in which the readout pad extends are different, and the band-shaped pattern and the readout pad face each other and intersect with each other (ST02).

### (Operation and Effects)

According to the quantum device manufacturing method of the present example embodiments, the band-shaped readout pad extending in the second direction faces and intersects with the band-shaped pattern extending in the first direction.

Accordingly, even if the readout pad deviates in the first direction or the second direction with respect to the band-shaped pattern, it is difficult for the area of the overlapping portion to change.

Therefore, the quantum device manufacturing method of the present example embodiments can curb changes in capacitive coupling.

Although the example embodiments of the present disclosure have been described above, these example embodiments are shown as examples and are not intended to limit the scope of the present disclosure. These example embodiments can be implemented in various other forms, and various omissions, substitutions, and changes can be made without departing from the gist of the present disclosure. Each example embodiment can be combined with other example embodiments as appropriate.

Some or all of the above example embodiments may be described as in the following supplementary notes, but the example embodiments are not limited to the following.

### (Supplementary Note 1)

A quantum device including:
a first chip including a quantum bit including a band-shaped pattern extending in a first direction; and
a second chip including a band-shaped readout pad extending in a second direction different from the first direction,
wherein the readout pad faces and intersects with the band-shaped pattern.

### (Supplementary Note 2)

The quantum device according to supplementary note 1, wherein the readout pad has a first pair of parallel sides that intersect with the band-shaped pattern, and a second pair of sides that do not intersect with the band-shaped pattern.

### (Supplementary Note 3)

The quantum device according to supplementary note 1 or 2, wherein the readout pad extends to both sides in a width direction of the band-shaped pattern with a width that is same as a width of an intersecting overlapping portion.

### (Supplementary Note 4)

The quantum device according to any one of supplementary notes 1 to 3, wherein the band-shaped pattern extends to both sides in a width direction of the readout pad with a width that is same as a width of an intersecting overlapping portion.

### (Supplementary Note 5)

The quantum device according to any one of supplementary notes 1 to 4, wherein a length of the readout pad in the second direction is greater than a width of the band-shaped pattern.

### (Supplementary Note 6)

The quantum device according to any one of supplementary notes 1 to 5, wherein the band-shaped pattern and the readout pad are capacitively coupled.

### (Supplementary Note 7)

The quantum device according to supplementary note 2, wherein the second chip further includes a lead line extending from the second pair of sides of the readout pad.

### (Supplementary Note 8)

The quantum device according to any one of supplementary notes 1 to 7,
wherein the quantum bit further includes a cross-shaped pattern, and
wherein the band-shaped pattern connects patterns of two adjacent arm parts of the cross-shaped pattern.

### (Supplementary Note 9)

A quantum device manufacturing method including:
preparing a first chip including a quantum bit including a band-shaped pattern and a second chip including a band-shaped readout pad; and
bonding the first chip and the second chip such that a first direction in which the band-shaped pattern extends and a second direction in which the readout pad extends are different from each other, and the band-shaped pattern and the readout pad face each other and intersect with each other.

### (Supplementary Note 10)

The quantum device manufacturing method according to supplementary note 9, wherein the first chip and the second chip are bonded such that the readout pad has a first pair of parallel sides that intersect with the band-shaped pattern and a second pair of sides that do not intersect with the band-shaped pattern.

### (Supplementary Note 11)

The quantum device manufacturing method according to supplementary note 9 or 10, wherein the first chip and the second chip are bonded such that the readout pad extends to both sides in a width direction of the band-shaped pattern with a width that is same as a width of an intersecting overlapping portion.

### (Supplementary Note 12)

The quantum device manufacturing method according to any one of supplementary notes 9 to 11, wherein the first chip and the second chip are bonded such that the band-shaped pattern extends to both sides in a width direction of the readout pad with a width that is same as a width of an intersecting overlapping portion.

### (Supplementary Note 13)

The quantum device manufacturing method according to any one of supplementary notes 9 to 12, wherein the first chip and the second chip are bonded such that a length of the readout pad in the second direction is greater than a width of the band-shaped pattern.

### (Supplementary Note 14)

The quantum device manufacturing method according to any one of supplementary notes 9 to 13, wherein the first chip and the second chip are bonded such that the band-shaped pattern and the readout pad are capacitively coupled.

### (Supplementary Note 15)

The quantum device manufacturing method according to supplementary note 10, wherein the second chip further includes a lead line extending from the second pair of sides of the readout pad.

### (Supplementary Note 16)

The quantum device manufacturing method according to any one of supplementary notes 9 to 15,
wherein the quantum bit further includes a cross-shaped pattern, and
wherein the band-shaped pattern connects patterns of two adjacent arm parts of the cross-shaped pattern.

According to the quantum device and quantum device manufacturing method according to the present disclosure, changes in capacitive coupling can be curbed.

What is claimed is:

1. A quantum device comprising:
a first chip including a quantum bit including a band-shaped pattern extending in a first direction; and
a second chip including a band-shaped readout pad extending in a second direction different from the first direction,
wherein the readout pad faces and intersects with the band-shaped pattern.

2. The quantum device according to claim 1, wherein the readout pad has a first pair of parallel sides that intersect with the band-shaped pattern, and a second pair of sides that do not intersect with the band-shaped pattern.

3. The quantum device according to claim 1, wherein the readout pad extends to both sides in a width direction of the band-shaped pattern with a width that is same as a width of an intersecting overlapping portion.

4. The quantum device according to claim 1, wherein the band-shaped pattern extends to both sides in a width direction of the readout pad with a width that is same as a width of an intersecting overlapping portion.

5. The quantum device according to claim 1, wherein a length of the readout pad in the second direction is greater than a width of the band-shaped pattern.

6. The quantum device according to claim 1, wherein the band-shaped pattern and the readout pad are capacitively coupled.

7. The quantum device according to claim 2, wherein the second chip further includes a lead line extending from the second pair of sides of the readout pad.

8. The quantum device according to claim 1,
wherein the quantum bit further includes a cross-shaped pattern, and
wherein the band-shaped pattern connects patterns of two adjacent arm parts of the cross-shaped pattern.

9. A quantum device manufacturing method comprising:
preparing a first chip including a quantum bit including a band-shaped pattern and a second chip including a band-shaped readout pad; and
bonding the first chip and the second chip such that a first direction in which the band-shaped pattern extends and a second direction in which the readout pad extends are different from each other, and the band-shaped pattern and the readout pad face each other and intersect with each other.

10. The quantum device manufacturing method according to claim 9, wherein the first chip and the second chip are bonded such that the readout pad has a first pair of parallel sides that intersect with the band-shaped pattern and a second pair of sides that do not intersect with the band-shaped pattern.

11. The quantum device manufacturing method according to claim 9, wherein the first chip and the second chip are bonded such that the readout pad extends to both sides in a width direction of the band-shaped pattern with a width that is same as a width of an intersecting overlapping portion.

12. The quantum device manufacturing method according to claim 9, wherein the first chip and the second chip are bonded such that the band-shaped pattern extends to both sides in a width direction of the readout pad with a width that is same as a width of an intersecting overlapping portion.

13. The quantum device manufacturing method according to claim 9, wherein the first chip and the second chip are bonded such that a length of the readout pad in the second direction is greater than a width of the band-shaped pattern.

14. The quantum device manufacturing method according to claim 9, wherein the first chip and the second chip are bonded such that the band-shaped pattern and the readout pad are capacitively coupled.

15. The quantum device manufacturing method according to claim 10, wherein the second chip further includes a lead line extending from the second pair of sides of the readout pad.

16. The quantum device manufacturing method according to claim 9,
wherein the quantum bit further includes a cross-shaped pattern, and
wherein the band-shaped pattern connects patterns of two adjacent arm parts of the cross-shaped pattern.
